(19) United States
(12) Patent Application Publication
(10) Pub. No.: US 2013/0180563 A1
(43) Pub. Date: Jul. 18, 2013

(54) THERMALLY SWITCHED THERMOELECTRIC POWER GENERATION

(71) Applicant: TEMPRONICS, INC., Tucson, AZ (US)

(72) Inventor: Tarek Makansi, Tucson, AZ (US)

(73) Assignee: TEMPRONICS, INC., Tucson, AZ (US)

(21) Appl. No.: 13/728,794

(22) Filed: Dec. 27, 2012

Related U.S. Application Data
(60) Provisional application No. 61/583,222, filed on Jan. 5, 2012.
(60) Provisional application No. 61/606,037, filed on Mar. 2, 2012.

(51) Int. Cl. H01L 35/06; H01L 35/32; H02J 7/34; H01L 35/30

(52) U.S. Cl. CPC H01L 35/06; H01L 35/30; H01L 35/32; H02J 7/345
USPC 136/206; 136/205; 320/101

(57) ABSTRACT

The Seebeck effect is the generation of a voltage between two junctions of dissimilar materials, and this effect is used to convert heat to electricity using thermoelectric modules containing a plurality of junctions. The efficiency of power generation using these modules is typically very low and much lower than rotating machines such as gas turbines and steam turbines combined with rotating electrical generators. This disclosure presents a method for increasing the efficiency of these thermoelectric modules significantly by thermally switching the heat source to the thermoelectric elements.

### CROSS REFERENCE TO RELATED APPLICATIONS

This application claims priority from U.S. Provisional Application Ser. No. 61/583,222, filed Jan. 5, 2012 and from U.S. Provisional Application Ser. No. 61/606,037, filed Mar. 2, 2012, the contents of which are incorporated hereby by reference.

### BACKGROUND OF THE INVENTION

Thermoelectric devices are versatile in that they can cool, heat, and convert heat to electricity. A single solid state device can accomplish all three of these functions. These devices are not used in large scale application, however, because of their poor efficiency. Instead, rotating machines like compressors, gas turbines, steam turbines, and electrical generators are used for these functions. The desire to use silent, solid state devices with no moving parts is very strong and hence the need for highly efficient thermoelectric devices is also very strong.

The understanding of the efficiency of thermoelectric devices has traditionally been defined for a static configuration of a constant temperature difference applied to either side of a semiconductor material. A voltage is generated in such a configuration that is proportional to the temperature difference, and this effect is called the Seebeck effect. Electrical power is generated from the temperature difference. Because semiconductor materials have high thermal conductivity, the conductive flow of heat from the hot side to the cold side dramatically reduces the energy conversion efficiency because this heat is wasted and not used to generate power. The traditional static configuration of temperatures applied to each side of the thermoelectric device results in conductive heat flow (loss) that is proportional to the temperature difference as described by the heat transfer equation.

In the prior art, switching of thermoelectric devices has been employed for cooling purposes. For example, see “Efficient Switched Thermoelectric Refrigerators for Cold Storage Applications” by U. Ghoshal and A. Guha, Journal of Electronic Materials DOI: 10.1007/s11664-009-0725-3, March 2009. In this paper, the authors describe how using a thermal diode and an electrical switch may be combined with a thermoelectric device to increase its efficiency in cooling applications. US patent application 2011/0016886 describes an implementation of the switched thermoelectric cooling system.

The prior art for cooling does not indicate how switching can increase the efficiency of a thermoelectric device when generating electricity from heat. An entirely different switching system is required to be combined with the thermoelectric device for power generation. In power generation mode, the thermoelectric module needs to be combined with a thermal switch and an electrical diode. In the prior art cooling mode, the additional components were a thermal diode and an electrical switch.

Thermal switching of a thermoelectric module for purposes of matching a temperature-varying energy source has been disclosed and analyzed in “Enhancing Thermoelectric Energy via Modulations of Source Temperature for Cyclical Heat Loadings” by R. McCarty, K. P. Hallinan, B. Sanders, and T. Somephone, Journal of Heat Transfer, Transactions of the ASME, Volume 129, June 2007, but this paper does not mention the use of thermal switching for a constant energy source wherein the switching is designed to increase conversion efficiency from heat to electricity.

Hence, the need exists for a more efficient configuration and use of thermoelectric devices for converting heat to electricity.

### SUMMARY OF THE INVENTION

In this invention, we allow the heat source to be coupled and decoupled dynamically in order to turn off the lossy conductive heat flow while still maintaining a temperature difference that can generate electricity for a period of time. The end result is electrical energy continues to be generated while the input heat is not being tapped, and the energy of the overall system is increased by several times.

In one aspect of the invention there is provided an electrical generator characterized by comprising, in combination, a thermoelectric module, a heat source, a thermal switch, and an electrical diode.

In one embodiment of the invention, the generator may include one or more of the following features:
(a) further including a capacitor for storing electrical energy;
(b) wherein the thermoelectric module preferably includes a semiconductor material; wherein the semiconductor material includes elements of both n and p types connected electrically in series;
(e) wherein the thermoelectric module contains one or more thermo-tunneling elements;
(d) wherein the heat source comprises a pipe with fluid flowing inside;
(e) wherein the heat source comprises sunlight collected onto a bulk material;
(f) wherein the heat source comprises flames or other hot gases;
(g) wherein the thermal switch comprises a motorized iris mechanism pushing one or more thermoelectric modules periodically against and periodically pulling away from the heat source;
(h) wherein the thermal switch is comprised of a memory metal whose shape changes with temperature adapted to periodically push the thermoelectric module against and periodically pull it away from the heat source;
(i) wherein the heat source comprises collected sunlight and the thermal switch is comprised of a concentrator that shifts the sunlight periodically to and periodically not to the thermoelectric module, wherein the shifting is accomplished by an actuator or by rotation of the earth or a combination thereof;
(j) wherein the thermoelectric modules are mounted on a linear tube which slides between a heat source and a cold source; wherein the tube preferably is motorized in a reciprocal fashion which causes the thermoelectric modules periodically to make contact with the heat source and periodically to remove them from the heat source; or wherein the tube is motorized in a rotary motion which causes the thermoelectric modules periodically to make contact with the heat source and periodically to remove them from the heat source;
(k) further including a voice coil motor which provides periodic forces for causing the thermoelectric module to make and break contact with the heat source; and
(l) wherein the thermoelectric module is encased in a vacuum enclosure.

In one embodiment, the generator may be characterized by further including a boundary material attached to the heat source.

In another embodiment, the generator may be characterized by one or more of the following features;
(a) wherein the thermoelectric module periodically makes contact with the boundary layer;
(b) wherein the boundary layer is made from a high thermal conductivity and high heat capacity material selected from the group consisting of copper, gold and silver; and
(c) wherein the boundary layer is optimized to rapidly raise the temperature of another material coming in contact with it; and wherein the boundary layer preferably is comprised of soft flexible graphite or metal to allow surface matching with one side of the thermoelectric module over a period of time.

In one embodiment of the invention the generator is characterized in that electrical power of a periodically varying voltage is collected over time and stored as electrical energy.

In another embodiment of the invention the generator may be characterized by one or more of the following features:
(a) further including a DC voltage converter to match the voltage of the generator with that of the load;
(b) including a synchronized inverter to match the AC voltage of the load;
(c) comprising multiple thermoelectric modules whose thermal switches are out of phase so as to provide a more constant voltage level over time; and
(d) wherein multiple thermoelectric modules are employed together with series and parallel electrical connections to achieve a desired voltage output level.

In one embodiment of the invention, the generator is characterized in that the thermal switch is a material whose thermal conductivity can change or be changed.

In another embodiment of the invention, the generator may be characterized by one or more of the following features:
(a) wherein the thermal switch comprises a material that changes state from crystalline to amorphous;
(b) wherein the thermal switch comprises carbon black;
(c) wherein the thermal switch comprises a material that changes phase from solid to liquid;
(d) wherein the change in thermal conductivity is activated by temperatures naturally occurring in the generator; and
(e) wherein the change in thermal conductivity is activated by an applied voltage by a voltage driver that is synchronized with the desired thermal switching.

### BRIEF DESCRIPTION OF THE DRAWINGS

FIG. 1 shows a basic thermoelectric element and how the Seebeck effect is employed to generate electricity from heat that is manifest as a temperature difference.

FIG. 2 shows the basic configuration of the invention wherein a thermoelectric module with a few elements is combined with a thermal switch and an electrical diode.

FIG. 3a is similar to FIG. 2, with the addition of a boundary layer to improve efficiency, and FIGS. 3b-3e are graphs showing the prior art (FIG. 3b) and examples of the present invention (FIGS. 3c-3e). showing the generation of electrical power over time as the heat source is switched on and then off.

FIGS. 4a-4c show three different embodiments for the thermal switching using mechanical motion.

FIG. 5 shows another embodiment of the invention where a tube with thermoelectric devices mounted on the outside slides into alternating contact with a hot source and then a cold source.

FIG. 6 shows another embodiment where the tube rotates instead of slides.

FIG. 7 shows another embodiment wherein a voice coil actuates the thermoelectric module in and out of contact with the heat source.

FIG. 8 is an apparatus used to measure the increased efficiency of the invention vs. the prior art static thermal environment.

FIG. 9 shows the voltage generated by the apparatus of FIG. 8 displayed on an oscilloscope.

FIG. 10 illustrates the calculations used to demonstrate the increased electrical energy that is generated with the invention switched thermal environment vs. the prior art static thermal environment.

### DETAILED DESCRIPTION OF THE PREFERRED EMBODIMENTS

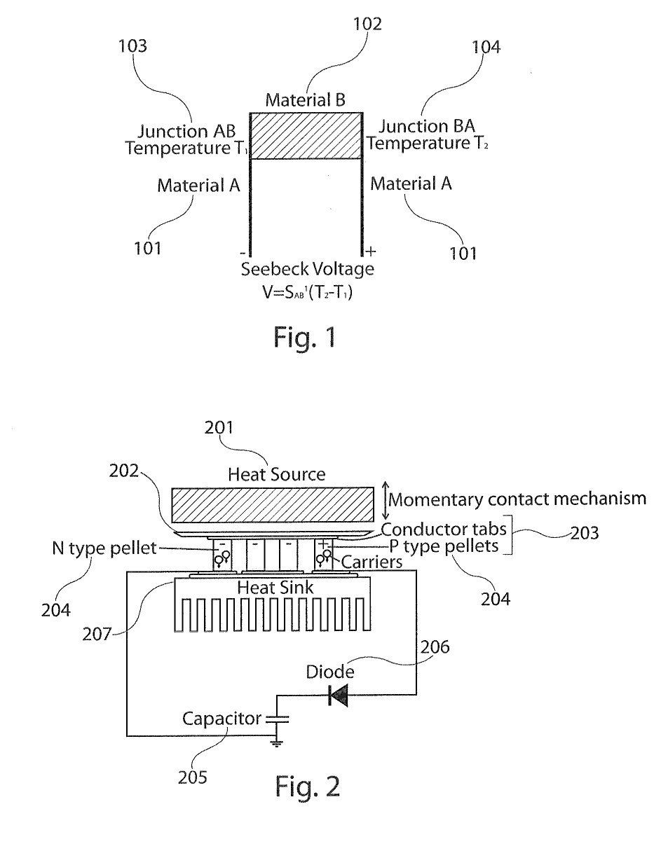

FIG. 1 illustrates the basic Seebeck effect for converting heat to electricity. Two materials A 101 and B 102 are joined at junctions AB 103 and BA 104. Typically material A 101 is a metal and material B 102 is a semiconductor. The voltage generated is proportional to the temperature difference T₂-T₁ and the constant of proportionality is the Seebeck coefficient S_{AB} of the two materials. In prior art implementations, a constant temperature difference is applied between the two junctions. The very low efficiency of this effect, even for optimized material selection, is due the high thermal conductivity of material B 102 causing much of the heat from the heat source to flow to the cold side. This flow of heat represents a loss for the module because it is not converted to electricity.

Heat flow through a material takes time, and the time constant of heat flow in FIG. 1 is the heat capacity of material B 102 times the thermal conductivity of material B 102. The Seebeck effect is immediate, however, and the voltage appearing across the junctions AB 103 and BA 104 is instantaneously equal to S_{AB}*(T₂−T₁), even prior to any heat flowing into material B. In this invention, the instantaneity of the Seebeck effect (power generation) in contrast with the delayed heat flow effect (loss) is exploited to achieve higher efficiency.

FIG. 2 illustrates the invention of switching the heat source 201 against the hot side 202 of a thermoelectric module 203. The thermoelectric module 203 consists of a plurality of junctions as illustrated in FIG. 1 connected electrically in series and thermally in parallel. The semiconductor material 204 alternates between n type and p type, which causes all of element voltages to sum together to produce the module voltage. In the prior art implementations, the heat source 201 would be in contact with one side of the module continuously. In this invention, the heat source is 201 in contact momentarily, and raises the temperature of the upper junctions to a high temperature. The electricity generated from this momentary contact is captured and stored in the capacitor 205. Before much of the heat from the heat source 201 flows into the semiconductor elements 204, the heat source 201 is pulled away from the upper junctions 207. As a result, the full Seebeck voltage is captured in the capacitor prior to the large losses from heat flow to the cold side 207 are able to occur.

The diode 206 in FIG. 2 prevents the electricity stored in the capacitor 205 from being delivered back to the thermoelectric module 203 when heat source 201 is not in contact.

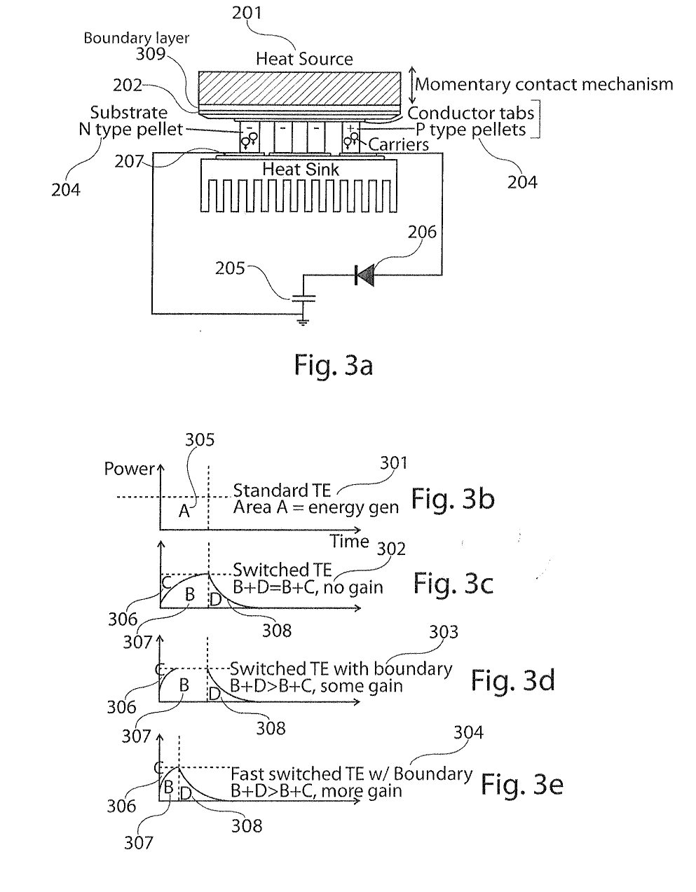

FIGS. 3b-3e show graphs of the behavior of the prior art (FIG. 3b) as well as the switched thermoelectric configuration of FIG. 2 with the addition of a boundary layer 309 (FIG. 3a) to improve efficiency further. For both the prior art (FIG. 3a) and the invention cases in FIGS. 3b-3e, the following assumptions are made: (1) the same thermoelectric module is used, (2) the heat source has the same temperature, and (3) the cold side has the same temperature.

On the right side of FIG. 3 are graphs of power output for several different types of boundary materials. The area under the curve of a power graph represents energy. The top graph 301 (FIG. 3b) shows the case for the prior art wherein the heat source 201 had been applied continuously and the junction temperatures have reached steady state. In this case, the area A 305 represents the total energy generated by the prior art approach with a static heat source. The remaining graphs show different cases of boundary layers attached to the heat source with the switching of the invention applied.

The second graph 302 (FIG. 3c) shows the case for a boundary layer 309 that has similar thermal and geometric properties as the thermoelectric semiconductor (low thermal conductivity and low heat capacity). In this case, the temperature (and hence the voltage generated) of the hot side 202 rises exponentially with a time constant of the boundary material 309. When the heat source 201 is removed, the voltage drops exponentially with a time constant of the thermoelectric material 204. In this case, the energy produced in this process is B+D which is approximately equal to area A=B+C, so not much gain over the prior art.

The third graph 303 (FIG. 3d) shows a case where the boundary layer 309 is chosen to have thermal properties opposite of the semiconductor 204, i.e. high heat capacity and high thermal conductivity. In this case, the temperature of the upper junctions 202 rises much faster, and so does the voltage as shown in the graph 303. Now, the total energy generated is B+D which is greater than the energy of the prior art A=B+C.

The fourth graph 304 (FIG. 3e) shows another case with the optimized boundary layer 202, but the contact time of the heat source 201 is reduced. In this case B+D>>B+C indicating an even greater benefit over the prior art (FIG. 3a).

As FIGS. 3b-3e illustrate, the benefit of the invention is maximized when the boundary layer material 201 is has the highest possible heat capacity and the highest possibly thermal conductivity. In this case, the momentary contact produces the fastest temperature rise in the upper junctions 202 and approaches the temperature of the heat source 201 with a minimal temperature gradient between the heat source 201 and the upper junctions 202.

Without limitation, in configuring the entire system for the invention, the heat source material is its original container, which could be water in a power plant, a selective surface for solar heat, a silicon chip for scavenging electronics heat, or whatever material happens to be the container of the heat. The thermoelectric module should be made from the highest ZT material that is practically available. The boundary layer is optimized to raise the junction temperature as fast as possible for the given heat source and the given thermoelectric module.

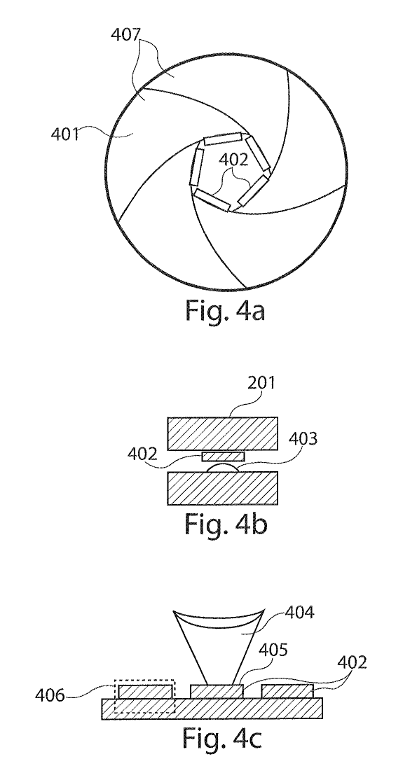

FIGS. 4a-4c show several embodiments for implementing the thermal switching portion of the invention. In all cases, it is assumed that the electrical output of the thermoelectric modules 402 is connected through a diode to an electrical load that receives the power generated, as illustrated in FIG. 2.

FIG. 4a shows an iris mechanism 401 used to push multiple thermoelectric modules 402 into a pipe or other heat source with a pentagonal cross-section. The thermoelectric modules 402 are shown at the ends of the iris mechanism 401, and the heat source is not shown but intended to be in the center. The iris mechanism 401 works similarly to that used to regulate the amount of light through a camera lens. As the iris segments 407 are rotated, the hole in the center becomes smaller thereby pushing one side of the thermoelectric modules temporarily against a heat source. The iris segments 407 are rotated by a motor, which is not shown in FIG. 4a, but said motor operates to achieve periodic momentary contact of the modules 402 to the heat source.

FIG. 4b shows another mechanism wherein a wire 403 made of nitinol or similar material changes its shape in response to temperature. The wire 403 is pre-programmed to have higher curvature when cold and lower curvature when hot. Then, it will pull the thermoelectric module 402 away from the heat source 201 when enough heat has traversed through the module to the nitinol 403, and will push the module 402 toward the heat source 201 when enough heat has dissipated from the module. A repetitive motion of contact and no contact can be achieved with the proper pre-programming of the nitinol wire 403.

FIG. 4c shows a third mechanism wherein the heat source is from concentrated sunlight 404. The sunlight 404 is concentrated on a selective surface 405 on one side of the module 402, heating it up. Later, the concentrated sunlight 404 is removed from this module 402 and, without limitation, shifted to another module. This movement of the concentrated light 404 may be achieved, without limitation, by physically moving the optics or by the rotation of the earth or a combination of these.

In all cases of FIGS. 4a-4c, the thermoelectric module 402 may be encased in a vacuum enclosure 406, as illustrated in FIG. 4c, to prevent premature oxidation or other degradation of the module parts from the intense heat.

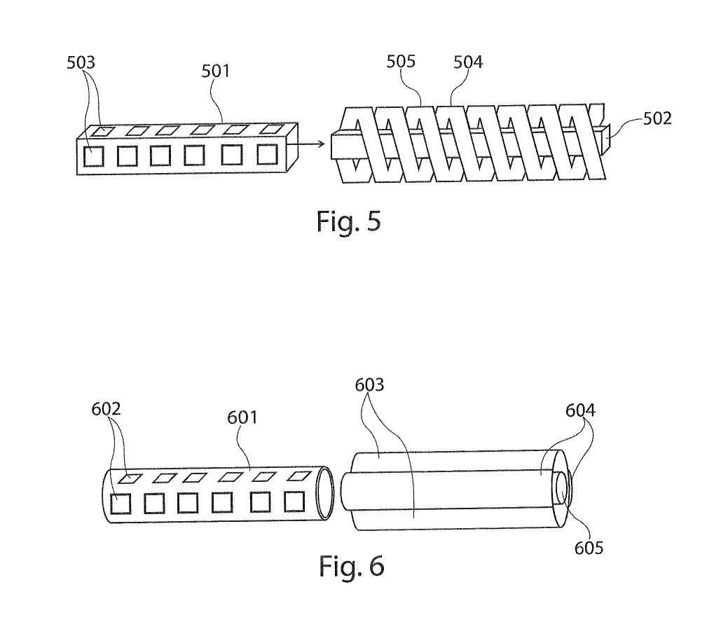

Another thermal switching mechanism is shown in FIG. 5. Here, a linear square pipe 502 in the center carries a cold fluid and a spiral hot-fluid pipe 504 has surfaces parallel to the central cold pipe 502. A linear, hollow, square tube 501 has thermoelectric devices 503 mounted on the sides. This tube slides in between the fluid-carrying pipes 502, 504, and 505. The inner sides of the thermoelectric modules 503 are always in thermal contact with the central cold pipe 502. The outer sides are either in thermal contact with a hot pipe 504 or, when the linear position of the tube is shifted, in thermal contact with another pipe 505. The second spiral pipe 505 is optional, but provides a means to remove, store, and recover heat from prior contacts with the hot spiral pipe 504.

In FIG. 5, a motorized or other mechanism (not shown) periodically shifts the tube 501 linearly to apply heat to the outer side of the thermoelectric modules 503 momentarily, then shifts back to stop drawing heat from the hot spiral pipe 504. By reciprocating the linear tube 501 back and forth, the thermal switching is accomplished to achieve the behavior and the gain in efficiency illustrated in FIGS. 3c-3e.

The reciprocating motion of the tube in FIG. 5 above might be difficult to achieve with inexpensive hardware. And, typically reciprocating motions require more energy than continuous rotary motion because of the momentum reversals. FIG. 6 illustrates a similar implementation as FIG. 5 but using rotary motion to accomplish the thermal switching.

In FIG. 6, the hollow tube 601 has a round cross section with curved thermoelectric devices mounted on it. Also, the spacing between the cold central pipe 605 and the linear outer pipes 603 and 604 has a round cross section that snugly accommodates the tube 601. By rotating the tube 601 inside the pipes, the outer sides of the thermoelectric modules 602 are placed in periodic momentary thermal contact with the hot pipe 604 while the inner side of the modules is always in contact with a cold pipe 605. The mechanism of FIG. 6 could also be reciprocating to avoid wrapping of wires or electrical brush contacts. The tube 601 with the thermoelectric modules 602 would rotate 90 degrees, and then rotate back -90 degrees in each cycle.

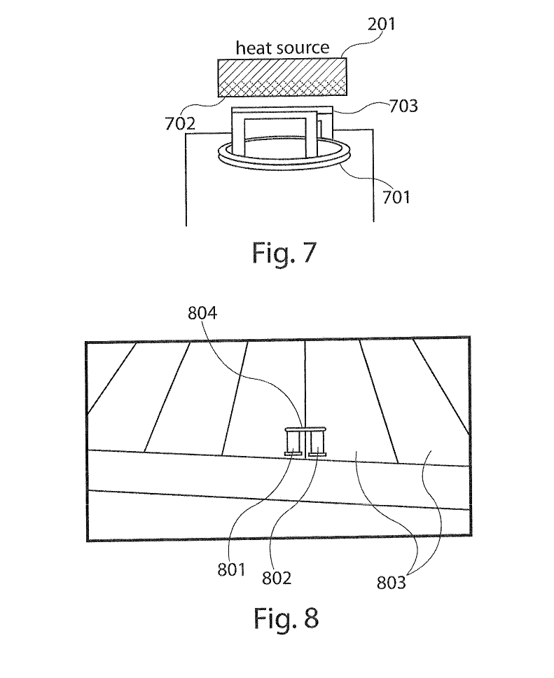

FIG. 7 shows another embodiment of the invention. A voice coil 701, which is commonly used in loudspeakers, is the actuating mechanism for pushing the thermoelectric module 703 into contact with the heat source 201, and then pulling it away. In this implementation, one watt of electrical power generated more than enough force in the voice coil 701 to lift the 256-element thermoelectric module 703. Without limitation, the contact side of the heat source 201 may include a layer of flexible, soft graphite film 702. These graphite films are available from GrafTech International of Parma, Ohio, USA, and they have thermal conductivity greater than 100 watts per meter per degree Kelvin, which is comparable to hard metals. Because of the softness of these graphite films, the surface will automatically conform to the irregularities on the hot side surface of the thermoelectric module 703, thereby making good thermal contact.

FIG. 8 shows a two-pellet embodiment of the invention wherein one element 801 is n-type and the other 802 is p-type. The bottoms of the elements are soldered to copper pads 803 on a circuit board 805. A thin copper foil bridge 804 is soldered to the tops of the elements. This copper bridge 804 is thick enough to have a small electrical resistance as compared to the two elements, but otherwise is as thin as possible to have minimal thermal mass. That is to say, the copper thickness is chosen to optimally trade off the energy losses of electrical resistance of the copper with the thermal mass of the copper. The small thermal mass allows for a fast temperature rise when the copper bridge 804 contacts the heat source. Because the generated electricity (Seebeck) is related to the temperature, a fast rise in temperature results in the most electrical energy generated.

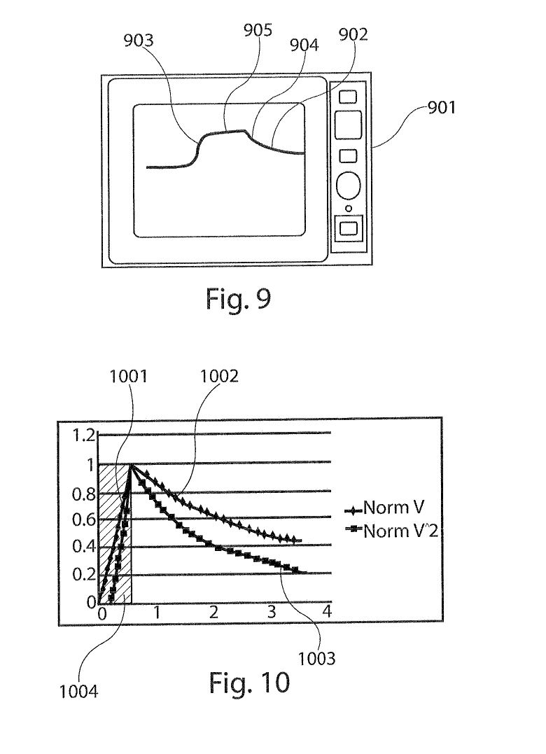

To measure the performance of the two-element embodiment of FIG. 8, a heat source with a flat surface (in this case a soldering pencil with a flat tip with an attached graphite pad) was brought downward and placed momentarily in contact with the copper bridge 804 in FIG. 8. The oscilloscope picture 901 in FIG. 9 shows the voltage produced 902. When the heat source was physically applied, the voltage ramped up quickly 903 as the temperature of the copper bridge 804 rose. When the heat source was physically removed, the voltage generated exhibited an exponential decrease 904 back to zero as shown in the trace of FIG. 9.

The rise time 903 in FIG. 9 was about 0.5 seconds, and this voltage rise is normalized and re-represented in the first 0.5 seconds of the blue-lined graph 1001 in FIG. 10. The exponential decay 904 after the heat was removed is copied to the rest of the blue line 1002 in FIG. 10. The flat portion 905 of the oscilloscope trace was taken out, simulating the removal of the heat source after 0.5 seconds.

In thermoelectric power generation, the electrical power generated is proportional to V², where V is the voltage if the load is resistive. The red line 1003 in FIG. 10 represents the square of the normalized voltage values in the blue line 1001 and 1002.

Energy is the integral of power over time. Graphically, energy is the area under the curve of power as a function of time. In FIG. 10, the area under the red line 1003 indicates the electrical energy that can be produced from the invention device if the heat source is in contact from time 0 to time 0.5 seconds. In prior art thermoelectric implementations, the heat source is connected in steady state with the hot side of the thermoelectric device. The voltage generated in steady state is a constant, and, after normalization, stays at a level of 1. The square of 1 is 1, so the normalized power produced is also 1 for the prior art implementation.

If we compare normalized electrical energy produced by the invention device (the area under the red line 1003 in FIG. 10) with the normalized electrical energy produced by the prior art thermoelectric device (the shaded area 1004 in FIG. 10), we see that the invention produced more electrical energy than the traditional thermoelectric device when the amount of heat input is the amount of heat drawn from the source between time 0 and time 0.5 seconds in FIG. 10.

The electrical energy generated may be compared quantitatively by computing the area under the red curve 1003 and comparing it to the shaded area 1004. The area under the red curve 1003, assuming the energy harvesting is stopped at time 3.5 seconds to be ready for the next cycle, is 1.55 normalized units. The shaded area 1004 representing the prior art thermoelectric device is 0.5 normalized units. Hence, the invention device produced three times as much electrical energy as the prior art for the same heat energy input.

In the embodiments described, the thermal switch was always shown as a physical mechanism that brought the hot side of the thermoelectric module in contact with the heat source momentarily and periodically. Without limitation, the thermal switch also could be accomplished by a layer of special material that changes its thermal conductivity momentarily and periodically. Phase change materials that have much greater thermal conductivity in the crystalline state and lower thermal conductivity in the amorphous state are an example of materials for this purpose. Carbon black materials that are used in resettable fuses also could serve this purpose. The material changes its state from crystalline when cold to amorphous when hot. Liquid crystal materials change their phase in response to an electrical potential, allowing for the thermal switch to be electrically activated and de-activated.

I claim:

1. An electrical generator comprised of a thermoelectric module, a heat source, a thermal switch, and an electrical diode.

2. The generator of claim 1 further including a capacitor for storing electrical energy.

3. The generator of claim 1 wherein the thermoelectric module includes a semiconductor material.

4. The generator of claim 3 wherein the semiconductor material includes elements of both n and p types connected electrically in series.

5. The generator of claim 1 wherein the thermoelectric module contains one or more thermo-tunneling elements.

6. The generator of claim 1 comprised of electrical connections on the hot side, said connections having high electrical conduction and low thermal mass.

7. The generator of claim 6 wherein the electrical connections are comprised of copper foil with a thin layer of solder connecting to the elements.

8. The generator of claim 6 wherein the electrical connections are patterned on a thin circuit board to connect multiple element pairs together.

9. The generator of claim 7, wherein the copper thickness is chosen to optimally trade off the energy losses of electrical resistance of the copper with the thermal mass of the copper.

10. The generator of claim 8 wherein the thin circuit board is comprised of plastic or glass or a combination of these.

11. The generator of claim 10, wherein the thin circuit board comprises a material selected from the group consisting of Kapton, polyimide, fiberglass, epoxy, and Teflon.

12. The generator of claim 1 wherein the heat source comprises a pipe with fluid flowing inside.

13. The generator of claim 1 wherein the heat source comprises sunlight collected onto a bulk material.

14. The generator of claim 1 wherein the heat source comprises flames or other hot gases.

15. The generator of claim 1 wherein the thermal switch comprises a motorized iris mechanism pushing one or more thermoelectric modules periodically against and periodically pulling away from the heat source.

16. The generator of claim 1 wherein the thermal switch is comprised of a memory metal whose shape changes with temperature adapted to periodically push the thermoelectric module against and periodically pull it away from the heat source.

17. The generator of claim 1 wherein the heat source comprises collected sunlight and the thermal switch is comprised of a concentrator that shifts the sunlight periodically to and periodically not to the thermoelectric module, wherein the shifting is accomplished by an actuator or by rotation of the earth or a combination thereof

18. The generator of claim 1 wherein the thermoelectric modules are mounted on a linear tube which slides between a heat source and a cold source.

19. The generator of claim 18 wherein the tube is motorized in a reciprocal fashion which causes the thermoelectric modules periodically to make contact with the heat source and periodically to remove them from the heat source.

20. The generator of claims 18 wherein the tube is motorized in a rotary motion which causes the thermoelectric modules periodically to make contact with the heat source and periodically to remove them from the heat source.

21. The generator of claim 1 further including a voice coil motor which provides periodic forces for causing the thermoelectric module to make and break contact with the heat source.

22. The generator of claim 1 wherein the thermoelectric module is encased in a vacuum enclosure.

23. The generator of claim 1 further including a boundary material attached to the heat source.

24. The generator of claim 23 wherein the thermoelectric module periodically makes contact with the boundary layer.

25. The generator of claim 23, wherein the boundary layer is made from a high thermal conductivity and high heat capacity material selected from the group consisting of copper, gold and silver.

26. The generator of claim 22, wherein the boundary layer is optimized to rapidly raise the temperature of another material coming in contact with it.

27. The generator of claim 26, wherein the boundary layer is comprised of soft flexible graphite or metal to allow surface matching with one side of the thermoelectric module over a period of time.

28. The generator of claim 1 wherein electrical power of a periodically varying voltage is collected over time and stored as electrical energy.

29. The generator of claim 28 further including a DC voltage converter to match the voltage of the generator with that of the load.

30. The generator of claim 28 including a synchronized inverter to match the AC voltage of the load.

31. The generator of claim 28, comprising multiple thermoelectric modules whose thermal switches are out of phase so as to provide a more constant voltage level over time.

32. The generator of claim 1, wherein multiple thermoelectric modules are employed together with series and parallel electrical connections to achieve a desired voltage output level.

33. The generator of claim 1, wherein the thermal switch is a material whose thermal conductivity can change or be changed.

34. The generator of claim 33 wherein the thermal switch comprises a material that changes state from crystalline to amorphous.

35. The generator of claim 34 wherein the thermal switch comprises carbon black.

36. The generator of claim 33 wherein the thermal switch comprises a material that changes phase from solid to liquid.

37. The thermal switch of claim 33 wherein the change in thermal conductivity is activated by temperatures naturally occurring in the generator.

38. The thermal switch of claim 33 wherein the change in thermal conductivity is activated by an applied voltage by a voltage driver that is synchronized with the desired thermal switching.
